(19) United States
(12) Patent Application Publication
(10) Pub. No.: US 2025/0233001 A1
(43) Pub. Date: Jul. 17, 2025

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Yutaka MOMIYAMA, Fukuoka (JP); Ikuo ITAKURA, Fukuoka (JP)

(21) Appl. No.: 19/012,188

(22) Filed: Jan. 7, 2025

(30) Foreign Application Priority Data
Jan. 16, 2024 (JP) 2024-004485

(51) Int. Cl. H01L 21/683; H01J 37/32

(52) U.S. Cl. CPC H01L 21/6833; H01J 37/32715; H01J 2237/2007

(57) ABSTRACT

An electrostatic chuck includes a dielectric substrate 100, an RF electrode provided inside the dielectric substrate, a base plate made of a metal and joined to the dielectric substrate, and a conductive member configured to electrically connect the RF electrode and the base plate to each other. A first recessed section which accommodates a part of the conductive member is formed on the surface on the base plate side of the dielectric substrate. A second recessed section which accommodates a part of the conductive member is formed on a surface on the dielectric substrate side of the base plate. In top view, the first recessed section is larger than the second recessed section.

### CROSS-REFERENCE TO RELATED APPLICATION

This application is based upon and claims the benefit of priority from Japanese Patent Application No. 2024-004485 filed on Jan. 16, 2024, the entire contents of which are incorporated herein by reference.

### FIELD

The present invention relates to an electrostatic chuck.

### BACKGROUND

For example, in a semiconductor manufacturing apparatus such as an etching apparatus, an electrostatic chuck is provided as an apparatus configured to attract and hold a wafer such as a silicon wafer to be processed. The electrostatic chuck includes a dielectric substrate to which an attraction electrode is provided and a base plate which supports the dielectric substrate, and has a configuration in which these are joined to each other. When a voltage is applied to the attraction electrode, an electrostatic force is generated, and the wafer placed on the dielectric substrate is attracted and held.

As described in International Publication No. WO 2022/255118, an RF electrode serving as one of a pair of counter electrodes configured to generate plasma in a semiconductor manufacturing apparatus may be built in the dielectric substrate. In this case, the RF electrode and the base plate are electrically connected to each other via a conductive member. According to this, a potential of the RF electrode during a process of the wafer is kept at a potential (for example, a ground potential) of the base plate.

### SUMMARY

To electrically connect the conductive member and the RF electrode to each other, for example, a recessed section may be formed on a surface on the base plate side in the dielectric substrate, and while the RF electrode is exposed in a bottom of the recessed section, the conductive member may be accommodated in an inner side of the recessed section. Similarly, to electrically connect the base plate and the RF electrode to each other, for example, a recessed section may be formed on a surface on the dielectric substrate side in the base plate, and the conductive member may be accommodated in the inner side of the recessed section. In this case, a part of the conductive member is accommodated in the recessed section of the dielectric substrate, and another part is accommodated in the recessed section of the base plate.

In such a configuration, in a case where an inner circumferential surface of the recessed section of the dielectric substrate is widely in contact with a lateral surface of the conductive member, heat transfer between the dielectric substrate and the conductive member is increased. As a result, a part in the vicinity of the conductive member in the dielectric substrate may be too excessively cooled down by the base plate via the conductive member. In a case where a heat output of the conductive member has increased along with energization of the RF electrode, the part in the vicinity of the conductive member in the dielectric substrate may be too excessively heated up by the conductive member. When the cooling or heating by the conductive member is excessively carried out, a fluctuation in an in-plane temperature distribution of the wafer during the process is increased.

The present invention has been made in view of such an issue and is aimed to provide an electrostatic chuck in which a fluctuation in an in-plane temperature distribution of a wafer during a process can be reduced.

To address the above-mentioned issue, an electrostatic chuck according to an aspect of the present invention includes a dielectric substrate including a placement surface on which an object to be attracted is placed, an internal electrode provided inside the dielectric substrate, a base plate made of a metal and joined to the dielectric substrate, and a conductive member configured to electrically connect the internal electrode and the base plate to each other. A first recessed section which accommodates a part of the conductive member is formed on a surface on the base plate side of the dielectric substrate, and a second recessed section which accommodates a part of the conductive member is formed on a surface on the dielectric substrate side of the base plate. When viewed from a direction perpendicular to the placement surface, the first recessed section is larger than the second recessed section.

By setting the first recessed section to be larger than the second recessed section, a gap can be formed between an inner circumferential surface of the first recessed section and a lateral surface of the conductive member, and heat transfer between those components can be reduced. Since local temperature increase or temperature decrease hardly occurs in the vicinity of the conductive member in the dielectric substrate, a fluctuation in an in-plane temperature distribution of a wafer during a process can be reduced.

According to the aspect of the present invention, it is possible to provide the electrostatic chuck in which the fluctuation in the in-plane temperature distribution of the wafer during the process can be reduced.

### BRIEF DESCRIPTION OF THE DRAWINGS

FIG. 1 is a cross sectional view schematically illustrating a configuration of an electrostatic chuck according to a first embodiment;

FIG. 2 is a cross sectional view illustrating a detail of a configuration of a conductive member and its neighboring part of the electrostatic chuck according to the first embodiment;

FIG. 3 is a perspective view illustrating the configuration of the conductive member; and

FIG. 4 is a cross sectional view illustrating a detail of the configuration of the conductive member and its neighboring part of the electrostatic chuck according to a second embodiment.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

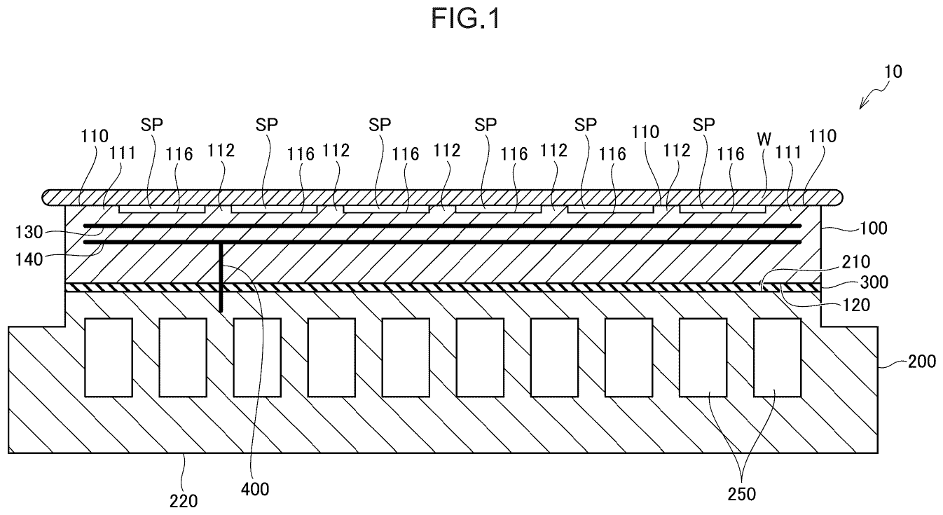

FIG. 1 is a cross sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300. A perspective in a case where the electrostatic chuck 10 is viewed from the surface 110 side along a direction perpendicular to the surface 110 will also be hereinafter expressed as “top view”.

An attraction electrode 130 is embedded inside the dielectric substrate 100. The attraction electrode 130 is a thin planar layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line which is not illustrated in the drawing, an electrostatic force is generated between the surface 110 and the wafer W, and according to this, the wafer W is attracted and held. As a configuration of the above-described feed line, various configurations in related art can be adopted. The single attraction electrode 130 may be provided as so-called a “monopolar” electrode as in the present embodiment, but may also include two attraction electrodes as so-called “bipolar” electrodes.

In addition to the attraction electrode 130 described above, an RF electrode 140 is also embedded inside the dielectric substrate 100. The RF electrode 140 is provided as one of a pair of counter electrodes configured to generate plasma in a semiconductor manufacturing apparatus. The other of the counter electrodes is provided in a position on an upper side relative to the electrostatic chuck 10 in the semiconductor manufacturing apparatus. When a high frequency alternating voltage is applied between these counter electrodes, the plasma is generated on the upper side of the wafer W to be used for the process such as film formation or etching on the wafer W. The RF electrode 140 corresponds to an “internal electrode” according to the present embodiment.

Similarly, as in the attraction electrode 130, the RF electrode 140 is a thin planar layer made of a metallic material such as, for example, tungsten. As a material of the RF electrode 140, molybdenum, platinum, palladium, and the like may be used in addition to tungsten. The RF electrode 140 is embedded in a position on the surface 120 side relative to the attraction electrode 130. Similarly, as in the attraction electrode 130, the RF electrode 140 is arranged to be parallel to the surface 110. The RF electrode 140 is a single electrode of a substantially circular shape in top view. A center of the RF electrode 140 in top view matches a center of the dielectric substrate 100.

A conductive member 400 is provided in the electrostatic chuck 10. The conductive member 400 is a member configured to electrically connect the RF electrode 140 and the base plate 200, which will be described below, to each other. By the conductive member 400, a potential of the RF electrode 140 during the process on the wafer W becomes the same as a potential of the base plate 200. In FIG. 1, the conductive member 400 is schematically depicted as a simple straight line. A specific shape of the conductive member 400 will be described below.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. The seal ring 111 is a circular protrusion formed on the surface 110 side. A distal end (upper end in FIG. 1) of the seal ring 111 serves as a part of the surface 110 and abuts against the wafer W. It can be mentioned that the distal end of the seal ring 111 is an outermost circumferential part of the surface 110 serving as the placement surface.

It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniform.

A part denoted by a reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. A distal end of each of the dots 112 becomes a part of the surface 110 and abuts against the wafer W. By providing the plurality of thus configured dots 112, warping of the wafer W is reduced.

The base plate 200 is a substantially disk-shaped member which supports the dielectric substrate 100. The base plate 200 is made of, for example, a metallic material such as aluminum. The base plate 200 is joined to the surface 120 of the dielectric substrate 100 via the joining layer 300. A surface 210 on the upper side in FIG. 1 in the base plate 200 serves as a “surface to be joined” which is joined to the dielectric substrate 100 via the joining layer 300.

The joining layer 300 is a layer provided between the dielectric substrate 100 and the base plate 200 to join those components. The joining layer 300 is provided by causing an adhesive made of an insulating material to be cured. According to the present embodiment, a silicone adhesive is used as the above-described adhesive. It is noted however that the joining layer 300 may be provided by causing an adhesive made of other types to be cured. In any case, in order that a thermal resistance between the dielectric substrate 100 and the base plate 200 is reduced, a material with a highest possible thermal conductivity is preferably used as the material of the joining layer 300.

An insulating film may be formed on a surface of the base plate 200. As the insulating film, for example, an alumina film formed by thermal splaying can be used. When the surface of the base plate 200 is covered by the insulating film, it is possible to increase a withstand voltage of the base plate 200.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed on a surface 220 opposite to the surface 210 in the base plate 200.

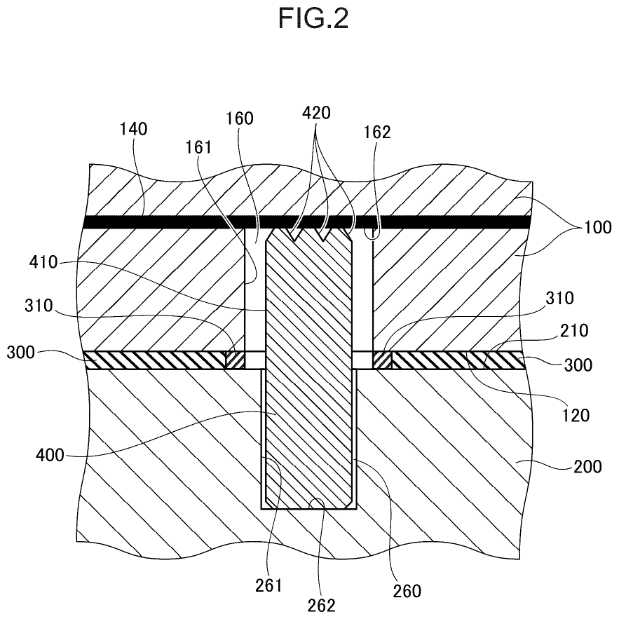

A specific configuration of the conductive member 400 and its neighboring part will be described with reference to FIG. 2. As illustrated in FIG. 2, a first recessed section 160 is formed on the surface 120 of the base plate 200 side of the dielectric substrate 100. The first recessed section 160 is a part provided by causing a part of the surface 120 to retreat towards the surface 110 in a recessed shape to enable the conductive member 400 to be arranged. The first recessed section 160 of the present embodiment is formed up to a depth position in which the RF electrode 140 is to be exposed. For this reason, the RF electrode 140 serving as the internal electrode is exposed in a bottom 162 of the first recessed section 160. A shape of the first recessed section 160 in top view is circular, and a space of a substantially cylindrical shape is formed in an inner side of the first recessed section 160.

A second recessed section 260 is formed on the surface 210 on the dielectric substrate 100 side of the base plate 200. The second recessed section 260 is formed in a position overlapped with the first recessed section 160 on the surface 210 in top view. The second recessed section 260 is a part provided by causing a part of the surface 210 to retreat towards the surface 220 in a recessed shape to enable the conductive member 400 to be arranged. A metallic part of the base plate 200 is exposed in whole in an inner side of the second recessed section 260. A shape of the second recessed section 260 in top view is circular, and a space of a substantially cylindrical shape is formed in the inner side of the second recessed section 260. A central axis of the second recessed section 260 matches a central axis of the first recessed section 160. It is however noted that a diameter of an inner circumferential surface 261 of the second recessed section 260 is smaller than a diameter of an inner circumferential surface 161 of the first recessed section 160.

A circular opening is formed in a part between the first recessed section 160 and the second recessed section 260 in the joining layer 300. The first recessed section 160 and the second recessed section 260 are connected to each other via the opening, and a whole of these becomes one space.

A member denoted by a reference sign “310” in FIG. 2 is a member arranged so as to avoid intrusion of an uncured adhesive into the inner sides of the first recessed section 160 and the second recessed section 260. The member will also be hereinafter referred to as a “blocking section 310”. The blocking section 310 is an annular member arranged so as to surround the first recessed section 160 over the whole circumference from the outer side in top view. An inner diameter of the blocking section 310 is the same as an inner diameter of a recessed section 121 but may have a size different from the inner diameter of the recessed section 121. As the blocking section 310, for example, a cured silicone adhesive is used.

The conductive member 400 is a member of a substantially cylindrical shape which is formed of a fibrous metal member, and is accommodated in the inner sides of the first recessed section 160 and the second recessed section 260. That is, a part of the conductive member 400 is accommodated in the first recessed section 160, and another part of the conductive member 400 is accommodated in the second recessed section 260. In top view, a diameter of the part accommodated in the first recessed section 160 in the conductive member 400 is equal to a diameter of the part accommodated in the second recessed section 260 in the conductive member 400.

The conductive member 400 abuts against the RF electrode 140 exposed in the bottom 162 of the first recessed section 160. The conductive member 400 also abuts against the metallic part of the base plate 200 which is exposed in a bottom 262 of the second recessed section 260. The RF electrode 140 and the metallic part of the base plate 200 are electrically connected to each other by the thus arranged conductive member 400.

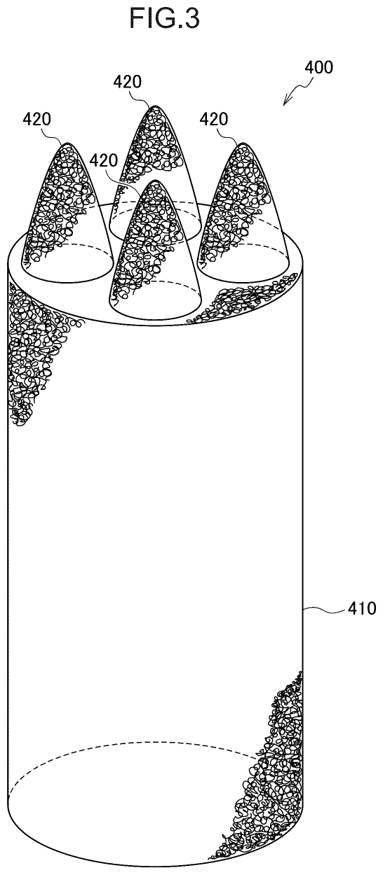

As illustrated in FIG. 3, the conductive member 400 includes a main body section 410 of a substantially cylindrical shape and a plurality of protrusion sections 420, and an entirety thereof is integrally formed of the fibrous metal member. The protrusion section 420 is a protrusion of a substantially cylindrical shape which is formed so as to extend from the surface on the dielectric substrate 100 side in the main body section 410 further towards the dielectric substrate 100. According to the present embodiment, four in total of the protrusion sections 420 are formed, but the number of the protrusion sections 420 may be different from four.

The conductive member 400 formed of the fibrous metal member has a breathability to such an extent that allows air or a fluid such as an adhesive to intrude into the inside of the conductive member 400. That is, the fibrous metal member is not sufficiently dense, and there is a gap between mutual fibers. When such a configuration is adopted, the conductive member 400 serves as an elastic body in which each section including the protrusion section 420 may be easily deformed by an external force.

A dimension in an up and down direction (direction in which the protrusion section 420 extends) of the conductive member 400 when the external force is not received is larger than a dimension in the same direction in the state of FIG. 2. That is, in a state in which the conductive member 400 is compressed along the direction from the dielectric substrate 100 towards the base plate 200, the conductive member 400 is accommodated in the inner sides of the first recessed section 160 and the second recessed section 260 and sandwiched between the RF electrode 140 and the base plate 200. A distal end of each of the protrusion sections 420 is elastically deformed so as to collapse by being pressed against the bottom 162 of the first recessed section 160 (that is, the RF electrode 140).

The conductive member 400 is in a state of being pressed against each of the RF electrode 140 and the base plate 200 by its own restoring force. For this reason, during the process on the wafer W or the like, even when a thermal expansion or contraction occurs in each section of the electrostatic chuck 10, the electrical connection between the RF electrode 140 and the base plate 200 may be regularly maintained.

The number of the conductive members 400 may be one or more. For example, a mode may be adopted in which a plurality of spaces composed of the first recessed section 160 and the second recessed section 260 are formed to be aligned along a circumferential direction, and the conductive members 400 are accommodated one by one in each of the spaces.

A shape different from that of the present embodiment may be adopted as the shape of the conductive member 400. For example, the entirety of the conductive member 400 may have a substantially cylindrical shape and a shape without including the protrusion section 420.

Since the conductive member 400 is a member made of a metal, a heat conductivity thereof is relatively high. For this reason, during the process on the wafer W, a part in the vicinity of the conductive member 400 in the dielectric substrate 100 may be too excessively cooled down by the base plate 200 via the conductive member 400. In a case where a heat output of the conductive member 400 has increased along with energization of the RF electrode 140, the part in the vicinity of the conductive member 400 in the dielectric substrate 100 may also be too excessively heated up by the conductive member 400. It is conceivable that the local cooling or heating by the conductive member 400 as described above is likely to occur, in particular, in a case where the inner circumferential surface 161 of the first recessed section 160 is widely in contact with a lateral surface of the conductive member 400.

When the local cooling or heating of the dielectric substrate 100 by the conductive member 400 is excessively carried out, the fluctuation in the in-plane temperature distribution of the wafer W during the process may be increased. In view of the above, in the electrostatic chuck 10 according to the present embodiment, the above-described issue may be to be addressed by devising the shapes of the first recessed section 160 and the second recessed section 260.

According to the present embodiment, the diameter of the inner circumferential surface 261 of the second recessed section 260 is approximately equal to the diameter of the main body section 410 of the conductive member 400. On the other hand, the diameter of the inner circumferential surface 161 of the first recessed section 160 is larger than the diameter of the inner circumferential surface 261 of the second recessed section 260. For this reason, in top view, the first recessed section 160 is larger than the second recessed section 260. The inner circumferential surface 161 of the first recessed section 160 is on an outer side relative to an inner circumferential surface 261 of the second recessed section 260 over a whole circumference.

When such a configuration is adopted, some degree of distance from the inner circumferential surface 161 of the first recessed section 160 to the lateral surface of the conductive member 400 can be secured over the whole circumference. Since a relatively large gap is formed between the inner circumferential surface 161 of the first recessed section 160 and the lateral surface of the conductive member 400, heat transfer between those components is reduced. As a result, since the local temperature increase or temperature decrease hardly occurs in the vicinity of the conductive member 400 in the dielectric substrate 100, it is possible to reduce the fluctuation in the in-plane temperature distribution of the wafer W during the process.

The diameter of the inner circumferential surface 261 of the second recessed section 260 may be larger than a diameter of the main body section 410 of the conductive member 400. In this case, too, the diameter of the inner circumferential surface 161 of the first recessed section 160 may be set to be even larger than the diameter of the inner circumferential surface 261 of the second recessed section 260.

A mode may be adopted where in top view, the inner circumferential surface 161 of the first recessed section 160 and the inner circumferential surface 261 of the second recessed section 260 are partly adjacent to each other or partly overlapped with each other. However, to sufficiently reduce the heat transfer between the dielectric substrate 100 and the conductive member 400, as in the present embodiment, the inner circumferential surface 161 of the first recessed section 160 and the inner circumferential surface 261 of the second recessed section 260 may be concentric in top view.

A configuration may be adopted in which the diameter of the part accommodated in the first recessed section 160 in the conductive member 400 and the diameter of the part accommodated in the second recessed section 260 in the conductive member 400 are different from each other. In this case, too, each of the first recessed section 160 and the second recessed section 260 may be formed such that the distance from the inner circumferential surface 161 of the first recessed section 160 to the lateral surface of the conductive member 400 is longer than the distance from the inner circumferential surface 261 of the second recessed section 260 to the lateral surface of the conductive member 400 over the whole circumference.

A second embodiment will be described. Hereinafter, an aspect different from the first embodiment will be mainly described, and descriptions of an aspect common to the first embodiment are not repeated as appropriate.

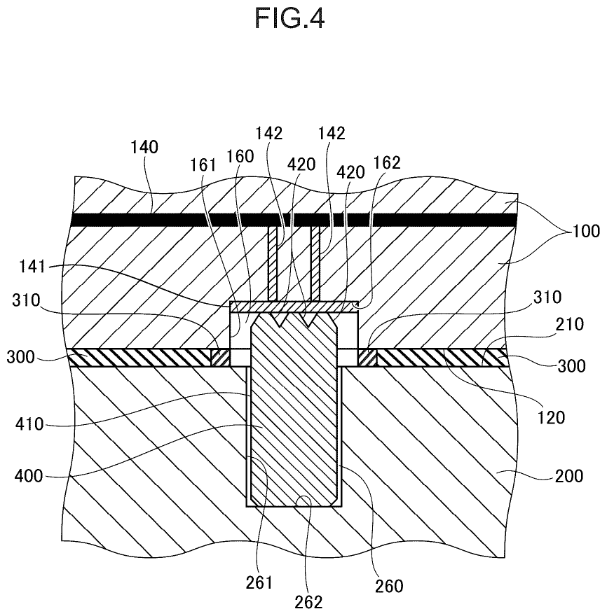

FIG. 4 depicts the configuration of the electrostatic chuck 10 according to the present embodiment from a perspective similar to that of FIG. 2. As illustrated in FIG. 4, the first recessed section 160 of the present embodiment is not formed up to the depth position in which the RF electrode 140 is to be exposed. The bottom 162 of the first recessed section 160 is in a position on the surface 120 side relative to the RF electrode 140.

The bottom 162 of the first recessed section 160 is covered by a metallic plate 141. The metallic plate 141 is a plate-like member made of, for example, molybdenum and is closely attached to substantially the whole of the bottom 162. A distal end of the protrusion section 420 is pressed against the metallic plate 141 according to the present embodiment.

The metallic plate 141 and the RF electrode 140 are electrically connected to each other by a plurality of via sections 142 provided in the dielectric substrate 100. The via section 142 is provided by filling the inner side of the hole formed so as to extend along the direction perpendicular to the surface 120 with a conductive member such as, for example, tungsten. One end of the via section 142 is connected to the metallic plate 141, and the other end is connected to the RF electrode 140.

In this manner, according to the present embodiment, the conductive member 400 and the RF electrode 140 are not directly connected to each other and are indirectly connected to each other via the metallic plate 141 and the via sections 142. In such a mode too, an effect similar to that described in the first embodiment can be attained.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed;
an internal electrode provided inside the dielectric substrate;
a base plate made of a metal and joined to the dielectric substrate; and
a conductive member configured to electrically connect the internal electrode and the base plate to each other, wherein
a first recessed section which accommodates a part of the conductive member is formed in a surface on a base plate side of the dielectric substrate,
a second recessed section which accommodates a part of the conductive member is formed in a surface on a dielectric substrate side of the base plate, and
when viewed from a direction perpendicular to the placement surface, the first recessed section is larger than the second recessed section.

2. The electrostatic chuck according to claim 1, wherein
when viewed from the direction perpendicular to the placement surface,
an inner circumferential surface of the first recessed section is on an outer side relative to an inner circumferential surface of the second recessed section over a whole circumference.

3. The electrostatic chuck according to claim 2, wherein
when viewed from the direction perpendicular to the placement surface,
a diameter of the part of the conductive member accommodated in the first recessed section is equal to a diameter of the part of the conductive member accommodated in the second recessed section.

4. The electrostatic chuck according to claim 1, further comprising:
a plate on the conductive member; and
a plurality of via sections extending from the plate and to the internal electrode.

5. The electrostatic chuck according to claim 1, further comprising:
a joining layer between the base plate and the dielectric substrate; and
a blocking section between the base plate and the dielectric substrate, the conductive member being spaced from the joining layer by the blocking section.

6. The electrostatic chuck according to claim 1, wherein the first recessed section and the second recessed section are circular, and the second recessed section has a smaller diameter than the first recessed section.

7. The electrostatic chuck according to claim 1, further comprising:
another internal electrode provided inside the dielectric substrate, the another internal electrode being spaced from the surface on the base plate side of the dielectric substrate by the internal electrode.
